(19) United States
(12) Patent Application Publication
(10) Pub. No.: US 2016/0056161 A1
(43) Pub. Date: Feb. 25, 2016

(54) MEMORY DEVICE

(71) Applicants: Hee Bum HONG, Hwaseong-si (KR); Lak GYO, Yongin-si (KR)

(72) Inventors: Hee Bum HONG, Hwaseong-si (KR); Lak GYO, Yongin-si (KR)

(21) Appl. No.: 14/692,999

(22) Filed: Apr. 22, 2015

(30) Foreign Application Priority Data
Aug. 25, 2014 (KR) 10-2014-0110661

(51) Int. Cl. H01L 27/11; H01L 27/092

(52) U.S. Cl. CPC H01L 27/1104; H01L 27/0924; H01L 27/0925

(57) ABSTRACT

A memory device including a substrate including a plurality of unit cell regions; a plurality of active regions on the substrate; and a plurality of gate electrodes on the substrate and extending in a first direction and intersecting at least one of the plurality of active regions, the plurality of active regions being adjacent to a boundary between the plurality of unit cell regions, and being separated from each other within the plurality of unit cell regions along a second direction orthogonal to the first direction.

### CROSS-REFERENCE TO RELATED APPLICATION

Korean Patent Application No. 10-2014-0110661, filed on Aug. 25, 2014, in the Korean Intellectual Property Office, and entitled: “Memory Device,” is incorporated by reference herein in its entirety.

### BACKGROUND

1. Field

The present disclosure relates to a memory device.

2. Description of the Related Art

A static random access memory (SRAM) that may be used, for example, in portable electronic products and in the cache memories of desktop or laptop computers, may have low power consumption and rapid operational speeds, and may not require refresh operations, unlike a dynamic random access memory (DRAM) using a capacitor. An SRAM may include a plurality of unit cell regions including a plurality of complementary metal-oxide-semiconductor (CMOS) elements. An SRAM provided as the CMOS elements may have superior low voltage characteristics and low standing current characteristics. For example, a dual-ported SRAM (DPSRAM), which may be capable of a synchronous read/write operation, may have a relatively rapid operational speed as compared to a single-ported SRAM.

### SUMMARY

Embodiments may be realized by providing a memory device, including a substrate including unit cell regions; active regions on the substrate; and gate electrodes on the substrate and extending in a first direction and intersecting at least one of the active regions, the active regions being adjacent to a boundary between the unit cell regions, and being separated from each other within the unit cell regions along a second direction orthogonal to the first direction.

The memory device may further include first connectors on the boundary between the unit cell regions; and second connectors between the gate electrodes within the unit cell regions. At least some of the second connectors may be disposed in different positions along the second direction.

Each of the active regions may include at least one fin structure.

At least some of the active regions may include different numbers of fin structures.

At least one of the second connectors may electrically connect fin structures included in different active regions to one another.

The at least one second connector electrically connecting fin structures included in the different active regions to one another may be provided as a path through which a current applied to the different active regions flows.

The first and second connectors may include a metallic silicide.

The active regions may include first conductive active regions and second conductive active regions.

The gate electrodes may include at least one path gate electrode intersecting at least one of the first conductive active regions; and at least one shared gate electrode intersecting the second conductive active regions and first conductive active regions not intersected by the at least one path gate electrode.

The memory device may further include at least one contact electrically connected to the active regions and at least one contact electrically connected to at least one of the gate electrodes.

The at least one contact connected to the active regions and the at least one contact connected to the gate electrodes may have different heights from one another.

Embodiments may be realized by providing a memory device, including a substrate including unit cell regions; active regions on the substrate; and gate electrodes intersecting at least one of the active regions, an interval between the gate electrodes in parallel in a single unit cell region from among of the unit cell regions being greater than an interval between the gate electrodes in parallel in adjacent unit cell regions from among the unit cell regions.

The interval between the gate electrodes in parallel in the single unit cell region may be two times greater than the interval between the gate electrodes in parallel in the adjacent unit cell regions.

The active regions may include first conductive active regions; and second conductive active regions, the gate electrodes including at least one path gate electrode; and at least one shared gate electrode, at least one of the first conductive active regions intersecting the at least one path gate electrode, and the second conductive active regions and first conductive active regions not intersecting the at least one path gate electrode intersect the at least one shared gate electrode.

The memory device may further include connectors electrically connected to at least one of the first conductive active regions and the second conductive active regions.

The connectors may include first connectors on a boundary between the unit cell regions; and second connectors within the unit cell regions.

The second connectors may be in parallel with the at least one path gate electrode and the at least one shared gate electrode.

The second connectors may be provided as a path through which a current transferred from the at least one of the first conductive active regions intersecting the at least one path gate electrode flows.

Each of the active regions may include at least one fin structure, and two or more fin structures included in the active regions may be electrically connected to one another by the connectors.

The at least one of the first conductive active regions and the at least one path gate electrode may provide at least one path transistor, and first conductive active regions not providing at least one path transistor, the second conductive active regions, and the at least one shared gate electrode may provide at least one inverter.

Embodiments may be realized by providing a memory device including transistors on a semiconductor substrate, the memory device including inverters; and path transistors each connected to at least one of an input terminal and an output terminal of each of the inverters, each of the inverters including a pull-up transistor and a pull-down transistor, and a current applied to a drain terminal of at least one turned-on path transistor being transferred through a conductive line connecting source terminals of the pull-up transistor and the pull-down transistor, to one another, included in one of the inverters connected to the at least one turned-on path transistor, when the at least one path transistor is turned on.

The memory device may further include gate electrodes on the semiconductor substrate and extending along a first direction; and active regions intersecting the gate electrodes. The transistors may be defined by the gate electrodes and the active regions.

The conductive line may include connectors interposed between the gate electrodes along a second direction orthogonal to the first direction.

The conductive line may include a metallic silicide.

Embodiments may be realized by providing a memory device, including a substrate; active regions on the substrate, each of the active regions including at least one fin structure and an insulating layer between adjacent fin structures in a first direction; and gate electrodes on the insulating layer and extending in the first direction and intersecting at least one of the active regions, an upper portion of fin structures exposed outward of the insulating layer being covered by one of the gate electrodes.

### BRIEF DESCRIPTION OF DRAWINGS

Features will become apparent to those of skill in the art by describing in detail exemplary embodiments with reference to the attached drawings in which:

FIG. 1 illustrates a circuit diagram of a memory device according to an exemplary embodiment of the present disclosure;

FIG. 2 illustrates a plan view of a memory device according to an exemplary embodiment of the present disclosure;

FIG. 3 illustrates a cross-sectional view of a memory device according to an exemplary embodiment of the present disclosure;

FIG. 4 illustrates a plan view of a memory device according to an exemplary embodiment of the present disclosure;

FIG. 5A illustrates a cross-sectional view of a memory device according to an exemplary embodiment of the present disclosure;

FIG. 5B illustrates an enlarged view of area A of FIG. 5A;

FIG. 6 illustrates a cross-sectional view of a memory device according to an exemplary embodiment of the present disclosure;

FIG. 7 illustrates a plan view of a memory device according to an exemplary embodiment of the present disclosure;

FIGS. 8 through 10 illustrate cross-sectional views of memory devices according to exemplary embodiments of the present disclosure;

FIG. 11 illustrates a plan view of a memory device according to an exemplary embodiment of the present disclosure;

FIG. 12 illustrates a cross-sectional view of a memory device according to an exemplary embodiment of the present disclosure;

FIG. 13 illustrates a plan view of a memory device according to an exemplary embodiment of the present disclosure;

FIG. 14 illustrates a cross-sectional view of a memory device according to an exemplary embodiment of the present disclosure;

FIG. 15 illustrates a plan view of a memory device according to an exemplary embodiment of the present disclosure; and

FIGS. 16 and 17 illustrate block diagrams of electronic devices including memory devices according to exemplary embodiments of the present disclosure.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

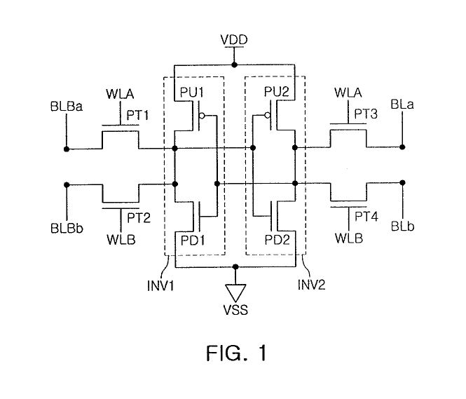

FIG. 1 illustrates a circuit diagram of a memory device according to an exemplary embodiment of the present disclosure.

Referring to FIG. 1, a memory device according to an exemplary embodiment of the present disclosure may include a unit cell region including eight transistors PU1, PU2, PD1, PD2, and PT1 to PT4. The memory device may include a plurality of unit cell regions. The eight transistors included in each unit cell region may be provided in a unit cell of a dual-ported static random access memory (SRAM) unit cell. As illustrated in FIG. 1, the unit cell region may include two inverters INV1 and INV2 including two pull-up transistors PU1 and PU2 and two pull-down transistors PD1 and PD2, and four path transistors PT1 to PT4 controlling operations of the inverters INV1 and INV2.

Gate terminals of the respective pull-up and pull-down transistors PU1 and PD1 included in the inverter INV1 may be connected to one another, and gate terminals of the respective pull-up and pull-down transistors PU2 and PD2 included in the inverter INV2 may be connected to one another. Each of the gate terminals may be connected to at least one of the path transistors PT1 to PT4. When a predetermined voltage is applied to a first word line WLA, the first and third path transistors PT1 and PT3 may be turned on, and data may be input/output through a first bit line BLa and a first complementary bit line BLBa. In a similar manner, when a predetermined voltage is applied to a second word line WLB, the second and fourth path transistors PT2 and PT4 may be turned on, and data may be input/output through a second bit line BLb and a second complementary bit line BLBb.

The plurality of unit cell regions in the circuit diagram as illustrated in FIG. 1 may form a single cell array. The cell array may be connected to a drive circuit via a word line WL and connected to a read/write circuit via a bit line BL. Drain terminals of the pull-up transistors PU1 and PU2 included in each unit cell region in the SRAM may require a predetermined voltage VDD to be applied thereto, and the cell array may be connected to a predetermined pull-up circuit.

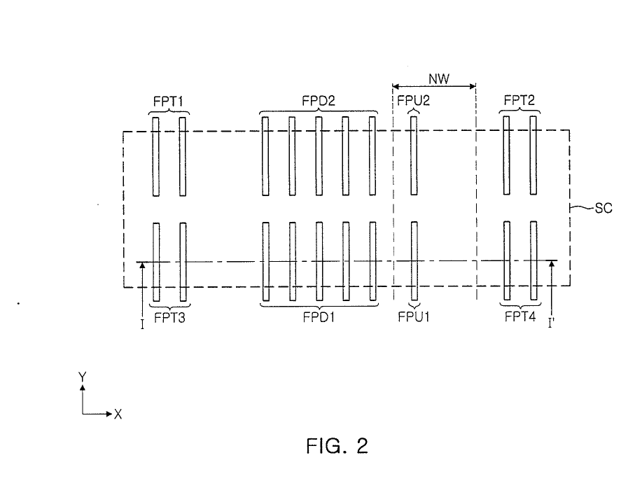

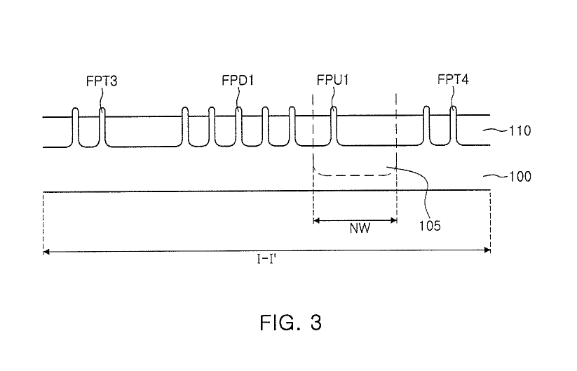

FIG. 2 illustrates a plan view of a memory device according to an exemplary embodiment of the present disclosure, and FIG. 3 illustrates a cross-sectional view of a memory device according to an exemplary embodiment of the present disclosure. For example, FIG. 3 illustrates a cross-sectional view of the memory device of FIG. 2 taken along line I-I′. FIGS. 2 and 3 illustrate views of a portion of layers in the memory device according to the exemplary embodiments.

Referring to FIGS. 2 and 3, the memory device according to the exemplary embodiment may include a semiconductor substrate 100. The semiconductor substrate 100 may provide a unit cell region SC accommodating a cell array, and the unit cell region SC may be the unit cell region of the SRAM.

The semiconductor substrate 100 may include a plurality of well regions. The pull-up transistors PU1 and PU2, provided as a p-type metal-oxide-semiconductor (PMOS) from among the eight transistors PU1, PU2, PD1, PD2 and PT1 to PT4 included in the unit cell region of the SRAM may be provided in an n-well region NW provided in a portion of the semiconductor substrate 100. A portion of the semiconductor substrate 100 other than the n-well region NW 105 may be provided as a region for providing the other transistors PD1, PD2, and PT1 to PT4 provided as n-type metal-oxide-semiconductors (NMOS). P-conductive well regions may be formed in the portion of the semiconductor substrate 100 other than the n-well region NW 105.

A plurality of fin structures FPU1, FPU2, FPD1, FPD2, and FPT1 to FPT4 may be formed on a top surface of the semiconductor substrate 100. The fin structures FPU1, FPU2, FPD1, FPD2, and FPT1 to FPT4 may be provided as active regions of the transistors PU1, PU2, PD1, PD2, and PT1 to PT4, respectively, included in the single unit cell region SC. Electrical characteristics of the transistors PU1, PU2, PD1, PD2, and PT1 to PT4 may be determined based on, for example, a number, a width, and a height, of the fin structures FPU1, FPU2, FPD1, FPD2, and FPT1 to FPT4.

For example, each of the four path transistors PT1 to PT4 included in the single unit cell region SC may include two fins in each of the fin structures. The four path transistors PT1 to PT4 may include the fin structures FPT1 to FPT4 being identical in terms of the form thereof, and the electrical characteristics of the four path transistors PT1 to PT4 may be substantially identical to one another.

The number of fins in each of the fin structures FPD1 and FPD2 included in the two pull-down transistors PD1 and PD2, respectively, may be five, the number being greater than the number of fins in each of the fin structures included in the path transistors PT1 to PT4, respectively. Only one fin may be included in the fin structures FPU1 and FPU2 included in the two pull-up transistors PU1 and PU2, respectively, the number being less than the number of fins in each of the fin structures included in the path transistors PT1 to PT4, respectively. FIG. 2 illustrates that, for example, the pull-down transistors PD1 and PD2 may have the greatest number of fins in each of the fin structures FPD1 and FPD2, and the pull-up transistors PU1 and PU2 may have the least number of fins in each of the fin structures FPU1 and FPU2.

An insulating layer 110 may be formed in a space defined by each of the fin structures FPU1, FPU2, FPD1, FPD2, and FPT1 to FPT4, and the top surface of the semiconductor substrate 100. The insulating layer 110 may include an oxide film, and in order to efficiently fill the space formed by the fin structures FPU1, FPU2, FPD1, FPD2, and FPT1 to FPT4 and the top surface of the semiconductor substrate 100, the insulating layer 110 may include a high density plasma (HDP) oxide film. Upper portions of the fin structures FPU1, FPU2, FPD1, FPD2, and FPT1 to FPT4 may be exposed through the insulating layer 110. The insulating layer 110 may be provided as a device isolation layer between the plurality of transistors PU1, PU2, PD1, PD2, and PT1 to PT4.

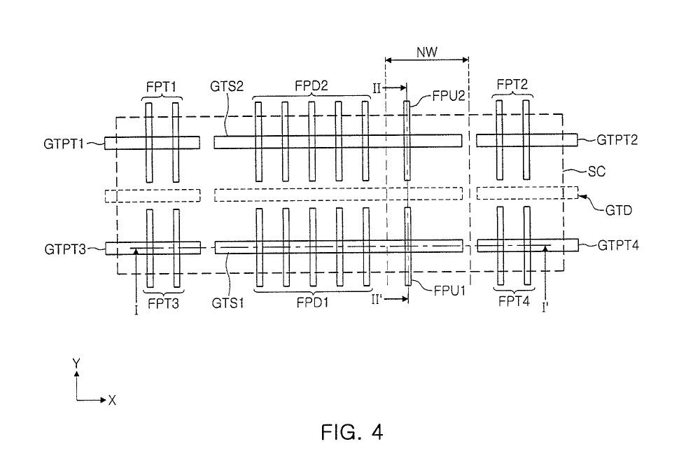

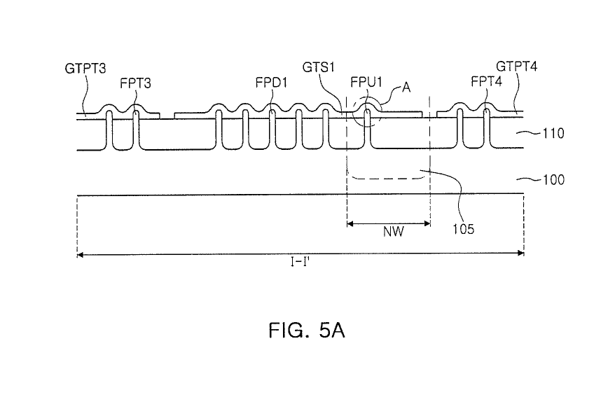

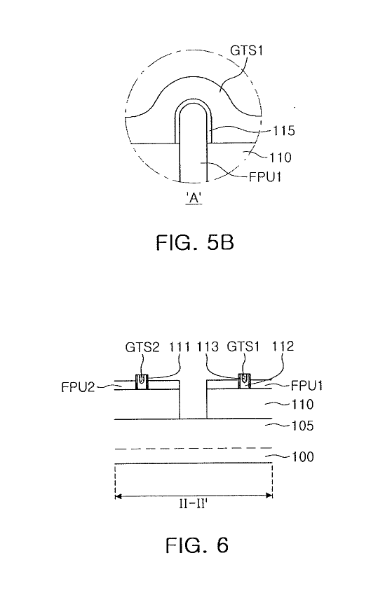

FIG. 4 illustrates a plan view of a memory device according to an exemplary embodiment of the present disclosure. A memory device according to an exemplary embodiment of the present disclosure will be described with reference to FIG. 4 along with FIGS. 5A, 5B, and 6. FIG. 5A illustrates a cross-sectional view of the memory device of FIG. 4 taken along line I-I′. FIG. 6 illustrates a cross-sectional view of the memory device of FIG. 4 taken along line II-II′.

Referring to FIG. 4, a plurality of gate electrodes GTS1, GTS2, and GTPT1 to GTPT4 may be formed on the fin structures FPU1, FPU2, FPD1, FPD2, and FPT1 to FPT4 formed on the semiconductor substrate 100 and the insulating layer 110. The plurality of gate electrodes GTS1, GTS2, and GTPT1 to GTPT4 may be provided on the insulating layer 110 while intersecting the plurality of fin structures FPU1, FPU2, FPD1, FPD2, and FPT1 to FPT4. A gate oxide layer for a passage of electrical charges may be disposed between the plurality of gate electrodes GTS1, GTS2, and GTPT1 to GTPT4 and the plurality of fin structures FPU1, FPU2, FPD1, FPD2, and FPT1 to FPT4.

The plurality of gate electrodes GTS1, GTS2, and GTPT1 to GTPT4 may extend along a first direction, e.g., an X axis direction in FIG. 4, and intersect the plurality of fin structures FPU1, FPU2, FPD1, FPD2, and FPT1 to FPT4. The plurality of fin structures FPU1, FPU2, FPD1, FPD2, and FPT1 to FPT4 may extend along a second direction, e.g., a Y axis direction in FIG. 4, intersecting the first direction, e.g., orthogonal to the first direction.

In the memory device according to the exemplary embodiment, the fin structures FPU1, FPU2, FPD1, FPD2, and FPT1 to FPT4 provided as the active regions of the transistors PU1, PU2, PD1, PD2, and PT1 to PT4, respectively, included in the unit cell region SC of the SRAM may be divided into portions along the Y axis direction, e.g., the second direction, in the unit cell region SC. For example, due to the fin structures FPU1, FPU2, FPD1, FPD2, and FPT1 to FPT4 not being connected but divided into portions along the second direction in the unit cell region SC, the unit cell region SC of the SRAM may secure a sufficient interval between word lines connected to the gate electrodes GTS1, GTS2, and GTPT1 to GTPT4.

The plurality of gate electrodes GTS1, GTS2, and GTPT1 to GTPT4 may include a plurality of shared gate electrodes GTS1 and GTS2 and a plurality of path gate electrodes GTPT1 to GTPT4. The shared gate electrodes GTS1 and GTS2 may be provided as gate electrodes of the pull-up transistors PU1 and PU2 and the pull-down transistors PD1 and PD2 included in the inverter INV1 and INV2. The path gate electrodes GTPT1 to GTPT4 may be provided as gate electrodes of the four path transistors PT1 to PT4 included in the unit cell region SC of the dual-ported SRAM, respectively.

The plurality of gate electrodes GTS1, GTS2, and GTPT1 to GTPT4 may include a high dielectric layer disposed in a space between gate spacers and a conductive layer provided in the high dielectric layer. The conductive layer may be provided in a narrow space in the high dielectric layer, and a level of electrical resistance of the conductive layer may be increased. If one of the shared gate electrodes GTS1 and GTS2 is provided as a path for current between the path transistors PT1 to PT4 and the pull-up or pull-down transistors PU1, PU2, PD1, and PD2, a mismatch between the path transistors PT1 to PT4 may occur, and a failure in the SRAM may result. According to the exemplary embodiment, the mismatch between the path transistors PTD1 to PD4 may be minimized by providing the shared gate electrodes GTS1 and GTS2 as the gate electrodes of the pull-up and pull-down transistors PU1, PU2, PD1, and PD2, and designing a layout of the unit cell region SC of the SRAM in which a current does not flow along the shared gate electrodes GTS1 and GTS2.

Referring to FIG. 5A, the plurality of gate electrodes GTS1, GTS2, and GTPT1 to GTPT4 may be disposed on the insulating layer 110 filling the space between the plurality of fin structures FPU1, FPU2, FPD1, FPD2, and FPT1 to FPT4. The plurality of gate electrodes GTS1, GTS2, and GTPT1 to GTPT4 may cover at least a portion of the fin structures FPU1, FPU2, FPD1, FPD2, and FPT1 to FPT4. A movement in electrical charges may occur in a region in which the fin structures FPU1, FPU2, FPD1, FPD2, and FPT1 to FPT4 and the gate electrodes GTS1, GTS2, and GTPT1 to GTPT4 overlap.

FIG. 5B illustrates an enlarged view of area A of FIG. 5A. Referring to FIG. 5B, a lateral surface of the fin structure FPU1 provided as the active region of the first pull-up transistor PU1 may be filled with the insulating layer 110, and an upper portion of the fin structure FPU1 exposed outwardly, e.g., exposed outward of the insulating layer 110, for example, due to the insulating layer 110 not being formed, may be covered by the first shared gate electrode GTS1. A gate oxide layer 115 may further be formed between the first shared gate electrode GTS1 and the fin structure FPU1. The gate oxide layer 115 is illustrated as a monolayer in FIG. 5B. In an embodiment, the gate oxide layer 115 may also be provided in a plurality of layers having different characteristics and materials.

FIG. 6 illustrates a cross-sectional view of the memory device illustrated in FIG. 4 taken along line Referring to FIG. 6, the n-well region NW 105 may be formed in the semiconductor substrate 100, and the fin structures FPU1 and FPU2 and the shared gate electrodes GTS1 and GTS2 may be provided on the n-well region NW 105. As illustrated in FIG. 4, the shared gate electrodes GTS1 and GTS2 may cover the upper portion of the fin structures FPU1 and FPU2 along a lengthwise direction of the fin structures FPU1 and FPU2, the second direction.

The shared gate electrodes GTS1 and GTS2 may include a gate spacer 111, a high dielectric layer 112 provided between the gate spacers 111, and a conductive layer 113 formed in the high dielectric layer 112. Hereinafter, a method of manufacturing the gate electrodes GTS1, GTS2, and GTPT1 to GTPT4 will be described with reference to FIGS. 4 and 6.

In a process of forming the gate electrodes GTS1, GTS2, and GTPT1 to GTPT4, dummy gate electrodes GTD may be formed on the fin structures FPU1, FPU2, FPD1, FPD2, and FPT1 to FPT4. The dummy gate electrodes GTD may extend along the first direction, e.g., the X axis direction in FIG. 4, each of which may be formed in three lines in the second direction within the unit cell region SC. For example, aside from what is illustrated in FIG. 4, the dummy gate electrodes GTD may be formed in an area in which the gate electrodes GTS1, GTS2, and GTPT1 to GTPT4 are to be formed.

The dummy gate electrodes GTD may be dummy electrodes which may receive damage that may occur in an ion implantation process, such as, for example, a Halo ion implantation process or a lightly doped drain (LDD) implantation process, subsequent to forming the gate spacer 111. The gate spacer 111 may not be formed on lateral surfaces of the dummy gate electrodes GTD disposed in a middle of the unit cell region SC along the second direction. For example, the gate spacer 111 may not be formed on the lateral surfaces of the dummy gate electrodes GTD that do not intersect the fin structures FPU1, FPU2, FPD1, FPD2, and FPT1 to FPT4.

The gate spacer 111 may be formed on the lateral surfaces of the dummy gate electrodes GTD intersecting the fin structures FPU1, FPU2, FPD1, FPD2, and FPT1 to FPT4, and when the ion implantation process, for example, is completed, the dummy gate electrodes GTD may be removed, and the dummy gate electrodes GTD formed in the middle of the unit cell region SC may be completely removed. When the dummy gate electrodes GTD are removed, the gate electrodes GTS1, GTS2, and GTPT1 to GTPT4 may be formed by filling the space between the gate spacers 111 with the high dielectric layer 112 and the conductive layer 113.

The dummy gate electrode GTD positioned in middle line of the three lines of dummy gate electrodes GTD formed within the unit cell region SC of the SRAM may be completely removed, and sufficient space between the gate electrodes GTS2, GTPT1, and GTPT2 disposed in a same position along the Y axis direction, e.g., the second direction, and the gate electrodes GTS1, GTPT3, and GTPT4 disposed in a same position along the Y axis direction, e.g., the second direction, in the unit cell region SC may be achieved. Accordingly, the space between the word lines extending along the first direction while being disposed on the gate electrodes GTS2, GTPT1, and GTPT2 and the gate electrodes GTS1, GPTP3, and GPTP4 may be sufficiently secured, and process stability may be enhanced and interference between the word lines may be minimized.

The dummy gate electrodes GTD may be formed in the three lines and removed, and an interval between the gate electrodes GTS1, GTS2, and GTPT1 to GTPT4 disposed in parallel and included in the single unit cell region SC may be greater than an interval between the gate electrodes GTS1, GTS2, and GTPT1 to GTPT4 disposed in parallel in adjacent unit cell regions SC. If all intervals between the three lines of the dummy gate electrodes GTD are the same as one another, the interval between the gate electrodes GTS1, GTS2, and GTPT1 to GTPT4 disposed in parallel and included in the single unit cell region SC may be two times greater than the interval between the gate electrodes GTS1, GTS2, and GTPT1 to GTPT4 disposed in parallel in the adjacent unit cell regions SC.

The gate electrodes GTS1, GTS2, and GTPT1 to GTPT4 may include the high dielectric layer 112 and the conductive layer 113 filling an interior of the high dielectric layer 112, and the gate electrodes GTS1, GTS2, and GTPT1 to GTPT4 may have a high level of resistance. According to the exemplary embodiment, the mismatch between the path transistors PT1 to PT4, for example, due to a difference in current paths, may be minimized by designing a layout of the unit cell region SC in which a current may not flowing along the gate electrodes GTS1, GTS2, and GTPT1 to GTPT4. The high dielectric layer 112 may include a dielectric material having a dielectric constant higher than that of a silicon oxide layer.

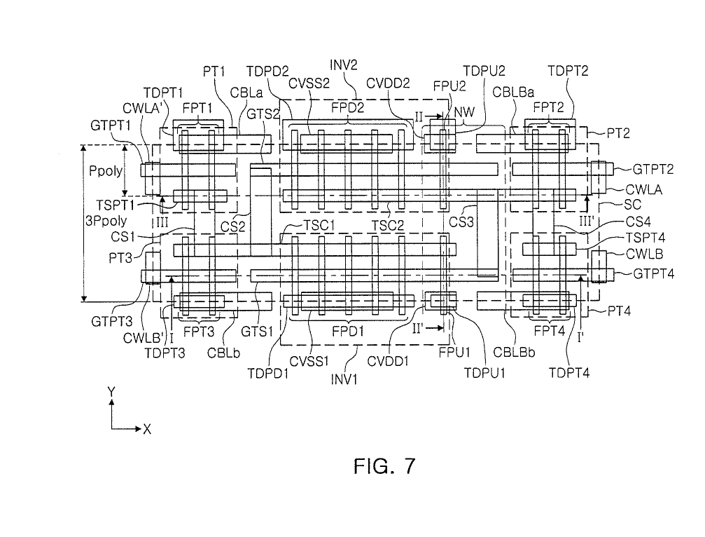

FIG. 7 illustrates a plan view of a memory device according to an exemplary embodiment of the present disclosure.

Referring to FIG. 7, in the unit cell region SC of the memory device according to the exemplary embodiment, the plurality of fin structures FPU1, FPU2, FPD1, FPD2, and FPT1 to FPT4 may be formed on the semiconductor substrate 100, and the gate electrodes GTS1, GTS2, and GTPT1 to GTPT may be provided on the plurality of fin structures FPU1, FPU2, FPD1, FPD2, and FPT1 to FPT4. The gate electrodes GTS1, GTS2, and GTPT1 to GTPT may extend along the first direction to intersect the plurality of fin structures FPU1, FPU2, FPD1, FPD2, and FPT1 to FPT4 extending along the second direction.

A plurality of connectors TDPT1 to TDPT4, TSPT1, TSPT4, TDPU1, TDPD2, TSC1, and TSC2 electrically connecting the fin structures FPU1, FPU2, FPD1, FPD2, and FPT1 to FPT4 included in the common transistors PU1, PU2, PD1, PD2, and PT1 to PT4 may be formed on the fin structures FPU1, FPU2, FPD1, FPD2, and FPT1 to FPT4. The plurality of connectors TDPT1 to TDPT4, TSPT1, TSPT4, TDPU1, TDPD2, TSC1, and TSC2 may be formed to fill the space between the fin structures FPU1, FPU2, FPD1, FPD2, and FPT1 to FPT4.

The plurality of connectors TDPT1 to TDPT4, TSPT1, TSPT4, TDPU1, TDPD2, TSC1, and TSC2 may include first connectors TDPT1 to TDPT4, TDPD1, TDPD2, TDPU1 and TDPU2 disposed on a boundary between the unit cell regions SC, and second connectors TSPT1, TSPT4, TSC1, and TSC2 disposed within the unit cell region SC. The first connectors TDPU1, TDPU2, TDPD1, TDPD2, and TDPT1 to TDPT4 may be provided as drain terminals of the transistors PU1, PU2, PD1, PD2, and PT1 to PT4, respectively. The second connectors TSPT1, TSPT4, TSC1, and TSC2 may be provided as source terminals of the transistors PU1, PU2, PD1, PD2, and PT1 to PT4, respectively.

For example, the first connector TDPD1 connected to a drain terminal of the first pull-down transistor PD1 may electrically connect the five fin structures provided as the active regions of the first pull-down transistor PD1. Similarly, the second connector TSPT1 may connect the two fins of the fin structure FPT1 to one another provided as the active regions of the first path transistor PT1.

The plurality of connectors TDPT1 to TDPT4, TSPT1, TSPT4, TDPU1, TDPD2, TDPD1, TDPD2, TSC1, and TSC2 and the gate electrodes GTS1, GTS2, and GTPT1 to GPTP4 may be connected to at least one of contactors, e.g., contacts, CBLa, CBLb, CBLBa, CBLBb, CVSS1, CVSS2, CVDD1, CVDD2, CWLA, CWLB, CWLA′, CWLB′, and CS1 to CS4. The plurality of connectors TDPT1 to TDPT4, TSPT1, TSPT4, TDPD1, TDPD2, TSC1, and TSC2 may be formed to fill the empty space between the fin structures FPU1, FPU2, FPD1, FPD2, and FPT1 to FPT4, and top surfaces of the gate electrodes GTS1, GTS2, GTPT1 to GTPT4 may have heights different from those of the plurality of connectors TDPT1 to TDPT4, TSPT1, TSPT4, TDPD1, TDPD2, TSC1, and TSC2, based on the top surface of the semiconductor substrate 100. Accordingly, the contactors, e.g., contacts, CS2 and CS3 connected directly to the gate electrodes GTS1, GTS2, and GTPT1 to GTPT4 may have heights different from those of the contactors, e.g., contacts, CBLa, CBLb, CBLBa, CBLBb, CVSS1, CVSS2, CVDD1, CVDD2, CWLA, CWLB, CWLA′, CWLB′, CS1, and CS4.

The contactors, e.g., contacts, CBLa, CBLb, CBLBa, CBLBb, CVSS1, CVSS2, CVDD1, CVDD2, CWLA, CWLB, CWLA′, CWLB′, and CS1 to CS4 may include first contactors, e.g., contacts, CBLa, CBLb, CBLBa, CBLBb, CVSS1, CVSS2, CVDD1, CVDD2, CWLA, CWLB, CWLA′, CWLB′ disposed on the boundary between the unit cell regions SC while being connected to at least one external line, and second contactors, e.g., contacts, CS1 to CS4 disposed within the unit cell region SC. The second contactors, e.g., contacts, CS1 to CS4 may connect at least one of the shared gate electrodes GTS1 and GTS2 and at least one of the second connectors TSC1 and TSC2 one another, or connect at least two of the second connectors TSPT1, TSPT4, TSC1, and TSC2 to one another.

The second connectors TSPT1, TSPT4, TSC1, and TSC2 disposed within the unit cell region SC may include a metallic silicide, for example, a tungsten silicide, and the second connectors TSPT1, TSPT4, TSC1, and TSC2 may have a relatively high electric conductivity as compared to the gate electrodes GTS1, GTS2, and GTPT1 to GTPT4. In the memory device according to the exemplary embodiment, a current path may be formed along at least one of the second connectors TSPT1, TSPT4, TSC1, and TSC2, a difference in current paths may be minimized, and the mismatch between the path transistors PT1 to PT4 may be reduced. For example, the at least one of the second connectors TSPT1, TSPT4, TSC1, and TSC2 may be provided as a conductive line through which a current transferred from the path transistors PT1 to PT4 flows.

If the second path transistor PT2 is turned on and a current signal is applied through the bit line BLBa connected to the drain terminal of the second path transistor PT2, the current signal may flow along the second connector TSC2 and be transferred to a source terminal of the second pull-down transistor PD2. If the first path transistor PT1 is turned on and a current signal is applied through the bit line BLa connected to the drain terminal of the first path transistor PT1, the current signal may flow along the second connector TSC1 and be transferred to a source terminal of the first pull-down transistor PD1. Current signals applied through the bit lines BLa, BLb, BLBa, and BLBb connected to the plurality of path transistors PT1 to PT4, respectively, may be transferred through paths having a similar length within the unit cell region SC, the mismatch between the path transistors PT1 to PT4, for example, due to a difference in current transfer paths, may be minimized, and operational failures may be prevented.

The plurality of connectors TDPT1 to TDPT4, TSPT1, TSPT4, TDPU1, TDPU2, TDPD2, TDPD2, TSC1, and TSC2 may be connected to the plurality of active regions FPU1, FPU2, FPD1, FPD2, and FPT1 to FPT4, and may each provide the drain or source terminal of each of the transistors PU1, PU2, PD1, PD2, and PT1 to PT4. In the layout of the unit cell region SC according to the exemplary embodiment, the plurality of active regions FPU1, FPU2, FPD1, FPD2, and FPT1 to FPT4 may be divided into portions along the second direction, e.g., a Y axis direction in FIG. 7, and the connectors TDPT1 to TDPT4, TSPT1, TSPT4, TDPU1, TDPU2, TDPD1, TDPD2, TSC1, and TSC2 may be disposed in four different positions that may be divided in the second direction within the single unit cell region SC.

Referring to FIG. 7, the connectors TDPT1 to TDPT4, TSPT1, TSPT4, TDPU1, TDPU2, TDPD1, TDPD2, TSC1, and TSC2 may be disposed on both sides of the active regions FPU1, FPU2, FPD1, FPD2, and FPT1 to FPT4. Accordingly, a height in the second direction of the single unit cell region SC may be trisected based on a position in the second direction at which the connectors TDPT1 to TDPT4, TSPT1, TSPT4, TDPU1, TDPU2, TDPD1, TDPD2, TSC1, and TSC2 are disposed. For example, the memory device according to the exemplary embodiment may have a structure in which the height of the single unit cell region SC is trisected.

As illustrated in FIG. 7, when an interval between sets of connectors disposed in common positions along the Y axis direction, e.g., the second direction, from among the connectors TDPT1 to TDPT4, TSPT1, TSPT4, TDPU1, TDPU2, TDPD1, TDPD2, TSC1, and TSC2 is defined as Ppoly, the height of the single unit cell region SC may be 3Ppoly. For example, the unit cell region SC included in the memory device according to the exemplary embodiment may have a 3 contacted poly pitch (3CPP) structure.

The second connectors TSC1, TSC2, TSPT1, and TSPT4 disposed within the unit cell region SC without being adjacent to the boundary of the unit cell regions SC may be disposed in different positions to one another in the second direction within the single unit cell region SC. Referring to FIG. 7, the second connectors TSC1 and TSPT4 and the second connectors TSC2 and TSPT1 may be disposed in different positions along the second direction. The second connectors TSC1 and TSPT4 may be in parallel with the second connectors TSC2 and TSPT1.

An interval in the second direction between the second connectors TSC1 and TSPT4 and the second connectors TSC2 and TSPT1 may be substantially the same as an interval in the second direction between the second connectors TSC1, TSC2, TSPT1, TSPT4 and the first connectors TDPT1, TDPD2, TDPU2, TDPT2, TDPT3, TDPD1, TDPU1, and TDPT4. Referring to FIG. 7, an interval between the connectors TDPT1 and TSPT1 included in the first path transistor PT1 may be substantially the same as an interval between the connectors TSC1 and TSC2 connected to the source terminals of the first and second pull-down transistors PD1 and PD2, respectively, and an interval between the connectors TDPT4 and TSPT4 included in the fourth transistor PT4.

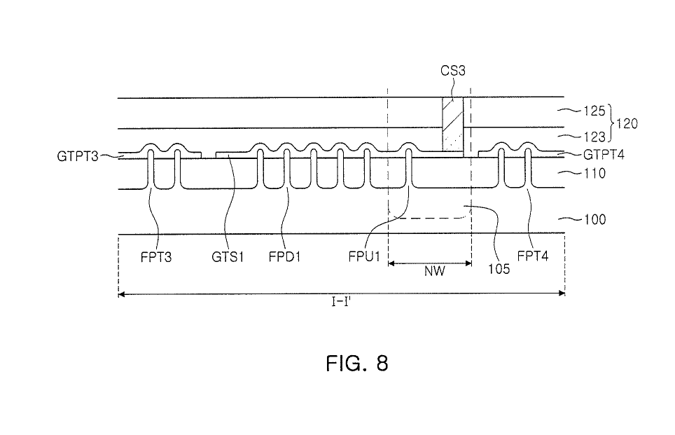

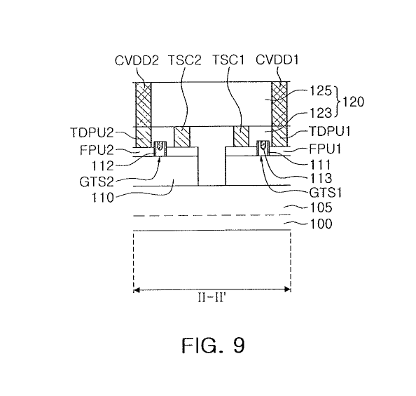

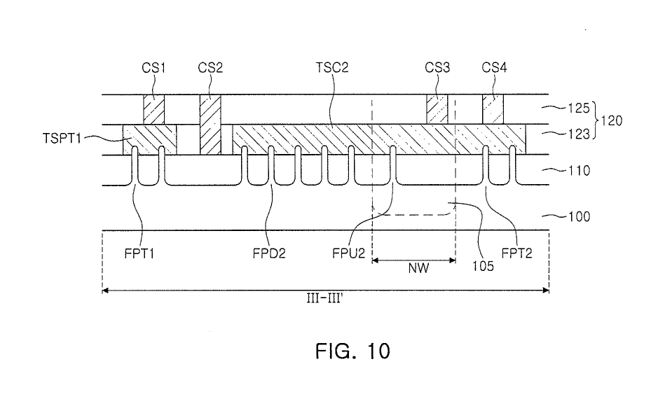

FIGS. 8 through 10 illustrate cross-sectional views of memory devices according to exemplary embodiments of the present disclosure. FIG. 8 illustrates a cross-sectional view of the memory device illustrated in FIG. 7 taken along line I-I′, and FIG. 9 illustrates a cross-sectional view of the memory device illustrated in FIG. 7 taken along line FIG. 10 illustrates a cross-sectional view of the memory device illustrated in FIG. 7 taken along line III-III′.

Referring to FIG. 8, the gate electrodes GTS1, GTPT3, and GTPT4 may be provided on the plurality of fin structures FPD1, FPU1, FPT3, FPT4 formed on the semiconductor substrate 100 and on the insulating layer 110 provided on the top surface of the semiconductor substrate 100. A portion of the shared gate electrode GTS1 provided as the gate terminal of the first pull-up and pull-down transistors PU1 and PD1 may be connected to the contactor CS3. The contactor CS3 connected to the shared gate electrode GTS1 may be electrically connected to the source terminal of each of the second pull-up transistor PU2, the pull-down transistor PD2 and the second path transistor PT2 through a connector TSC2.

The contactor CS3 may be formed by depositing an inter-insulating layer 120 on the gate electrodes GTS1, GTPT3, GTPT4 and the insulating layer 110, removing an area corresponding to the contactor CS3 by using an etching process, and filling the area with a conductive material. The inter-insulating layer 120 may include a first inter-insulating layer 123 and a second inter-insulating layer 125. The first inter-insulating layer 123 may have a height substantially the same as heights of the connectors TDPT1, TSPT1, TDPT2, TDPT3, TDPT4, TSPT4, TDPU1, TDPU2, TDPD1, TDPD2, TSC1, and TSC2 formed in a portion of the unit cell region SC.

Referring to FIG. 9, the plurality of fin structures FPU1 and FPU2 may be formed on the semiconductor substrate 100 on which the n-type well region 105 is formed. A portion of the fin structures FPU1 and FPU2 may be covered by the insulating layer 110, and the gate electrodes GTS1 and GTS2 and the connectors TDPU1, TDPU2, TSC1, and TSC2 may be formed in an exposed area of the fin structures FPU1 and FPU2 without being covered by the insulating layer 110.

To form the connectors TDPU1, TDPU2, TSC1, and TSC2, the first inter-insulating layer 123 may be formed to cover the gate electrodes GTS1 and GTS2, the fin structures FPU1 and FPU2, and the semiconductor substrate 100. Subsequent to forming the first inter-insulating layer 123, an area in which the connectors TDPU1, TDPU2, TSC1, and TSC2 are to be formed, through an etching process, may be removed, the removed area may be filled with a metallic silicide, and the connectors TDPU1, TDPU2, TSC1, and TSC2 may be formed. The connectors TDPU1, TDPU2, TSC1, and TSC2 may include a tungsten silicide.

After forming of the connectors TDPU1, TDPU2, TSC1, and TSC2, the second inter-insulating layer 125 may be formed on the first inter-insulating layer 123. An area in which the contactors, e.g., contacts, CVDD1 and CVDD2 are to be formed may be removed from the second inter-insulating layer 125, by using the etching process, the removed area may be filled with a conductive material, and the contactors, e.g., contacts, CVDD1 and CVDD2 may be formed. A portion of the second inter-insulating layer 125 may be removed to allow bottom surfaces of the contactors, e.g., contacts, CVDD1 and CVDD2 to contact top surfaces of the connectors TDPU1 and TDPU2.

Referring to FIG. 10, the connectors TSPT1 and TSC2 may be formed on the fin structures FPT1, FPD2, FPU2, and FPT2 provided on the semiconductor substrate 100. In a manner dissimilar to that of the source terminal of the first path transistor PT1 being separately connected to the single connector TSPT1, the source terminals of the second pull-up and pull-down transistors PU2 and PD2 and the second path transistor PT2 may be commonly connected to the single connector TSC2.

The connector TSC2 connected to each of the source terminal of the second pull-up and pull-down transistors PU2 and PD2 and the second path transistor PT2 may be connected to the contactors, e.g., contacts, CS3 and CS4. The contactor CS3 disposed in the n-type well region 105 may be connected to the shared gate electrode GTS1 of the first pull-up and pull-down transistors PU1 and PD1. The contactor CS4 may be connected to the connector TSPT4 disposed in the source terminal of the fourth path transistor PT4. The contactor CS1 connected to the connector TSPT1 disposed in the source terminal of the first path transistor PT1 may be connected to the connector TSC1 connected to the source terminal of each of the second pull-up and pull-down transistors PU2 and PD2 and the third path transistor PT3.

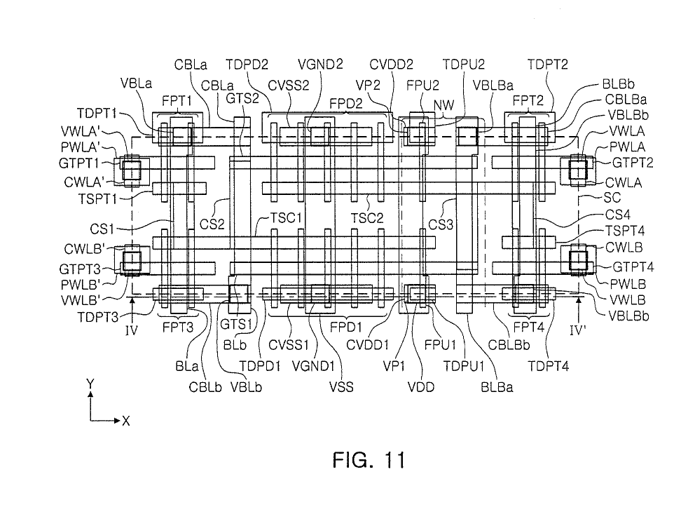

FIG. 11 illustrates a plan view of a memory device according to an exemplary embodiment of the present disclosure.

Referring to FIG. 11, metal lines are illustrated in addition to the plan view of FIG. 7. For example, the additional metal lines illustrated in FIG. 11 may be the bit lines BLa, BLb, BLBa, and BLBb, a power line VDD, and a ground line VSS electrically each connected to the drain terminal of each of the transistors PU1, PU2, PD1, PD2, PT1, PT2, PT3, and PT4 or the source terminal of each of the transistors PU1, PU2, PD1, PD2, PT1, PT2, PT3, and PT4.

The first and second bit lines BLa and BLb may be connected to the contactors, e.g., contacts, CBLa and CBLb, respectively, and the contactors, e.g., contacts, CBLa and CBLb may be disposed in the drain terminal of the first path transistor PT1 and the drain terminal of the third path transistor PT3, respectively. The first and second complementary bit lines BLBa and BLBb may be connected to the contactors, e.g., contacts, CBLBa and CBLBb, respectively, and the contactors, e.g., contacts, CBLBa and CBLBb may be disposed in the drain terminal of the second path transistor PT2 and the drain terminal of the fourth path transistor PT4, respectively. The power line VDD may be connected to the contactors, e.g., contacts, CVDD1 and CVDD2, disposed in the drain terminals of the pull-up transistors PU1 and PU2, respectively. The ground line VSS may be connected to the contactors, e.g., contacts, CVSS1 and CVSS2, disposed in the drain terminals of the pull-down transistors PD1 and PD2, respectively.

Each of the bit lines BLa, BLb, BLBa, and BLBb, the power line VDD, and the ground line VSS may include at least one via. For example, the power line VDD may include a first power via VP1 electrically connected to the contactor CVDD1 disposed in the drain terminal of the first pull-up transistor PU1, and a second power via VP2 electrically connected to the contactor CVDD2 disposed in the drain terminal of the second pull-up transistor PU2. Similarly, the second bit line BLb may include a second bit line via VBLb connected to the contactor CBLb disposed in the drain terminal of the third path transistor PT3.

Word line pads PWLA, PWLA′, PWLB, and PWLB′ may be formed on the gate electrodes GTPT1 to GTPT4 of the respective path transistors PT1 to PT4 connected to the word lines WLA and WLB, respectively. Vias VWLA, VWLA′, VWLB, and VWLB′ may be formed within the word line pads PWLA, PWLA′, PWLB, and PWLB′, respectively. The vias VWLA, VWLA′, VWLB, and VWLB′ may be respectively connected to the contactors, e.g., contacts, CWLA, CWLA′, CWLB, and CWLB′ disposed on the gate electrodes GTPT1 to GTPT4 of the path transistors PT1 to PT4, respectively.

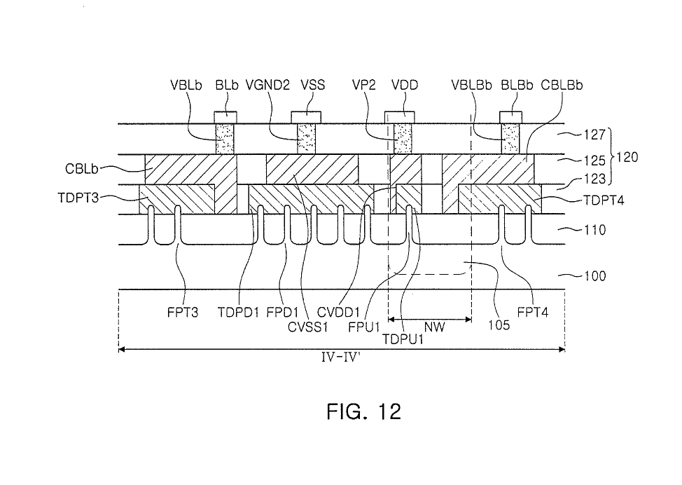

Hereinafter, a description pertaining to a cross-section of the memory device illustrated in FIG. 11 taken along line IV-IV′ will be provided with reference to FIG. 12.

FIG. 12 illustrates a cross-sectional view of a memory device according to an exemplary embodiment of the present disclosure. Referring to FIG. 12, the plurality of fin structures FPT3, FPD1, FPU1, and FPT4 is formed on the semiconductor substrate 100, and a space between the plurality of fin structures FPT3, FPD1, FPU1, and FPT4 and the semiconductor substrate 100 may be filled with the insulating layer 110. A portion of the semiconductor substrate 100 may be doped with n-type impurities, and provided as the n-type well region 105. The PMOS pull-up transistors PU1 and PU2 may be formed on the n-type well region 105.

The first inter-insulating layer 123 may be formed on the insulating layer 110, a portion of the first inter-insulating layer 123 may be removed by using an etching process, the removed portion of the first inter-insulating layer 123 may be filled with a conductive material, and the connectors TDPD1, TDPU1, TDPT3, and TDPT4 may be formed. The connectors TDPD1, TDPT3, and TDPT4 may electrically connect the plurality of fin structures FPT3, FPD1, and FPT4 to one another.

When the connectors TDPD1, TDPU1, TDPT3, and TDPT4 are formed, the second inter-insulating layer 125 may be formed on the first inter-insulating layer 123, a portion of the second inter-insulating layer 125 may be etched, the etched portion of the second inter-insulating layer 125 may be filled with a conductive material, and the contactors, e.g., contacts, CBLb, CVSS1, CVDD1, and CBLBb may be formed. The contactors, e.g., contacts, CBLb, CVDD1, and CBLBb may penetrate through the first and second inter-insulating layers 123 and 125 so as to contact a top surface of the insulating layer 110.

When the contactors, e.g., contacts, CBLb, CVSS1, CVDD1, and CBLBb are formed, a third inter-insulating layer 127 may be formed on the second inter-insulating layer 125. A portion of the third inter-insulating layer 127 may be etched, the etched portion of the third inter-insulating layer 127 may be filled with a conductive material, and the vias VBLb, VGND2, VP2, and VBLBb may be formed. The vias VBLb, VGND2, VP2, and VBLBb may be connected to the bit lines BLb and BLBb, the power line VDD, and the ground line VSS, respectively.

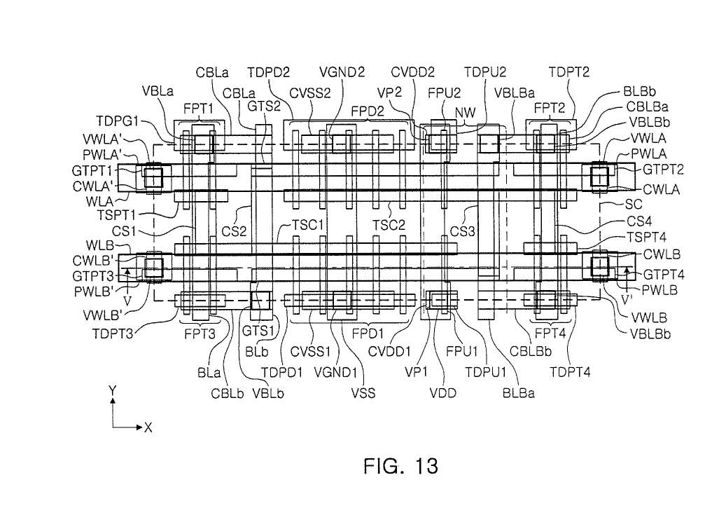

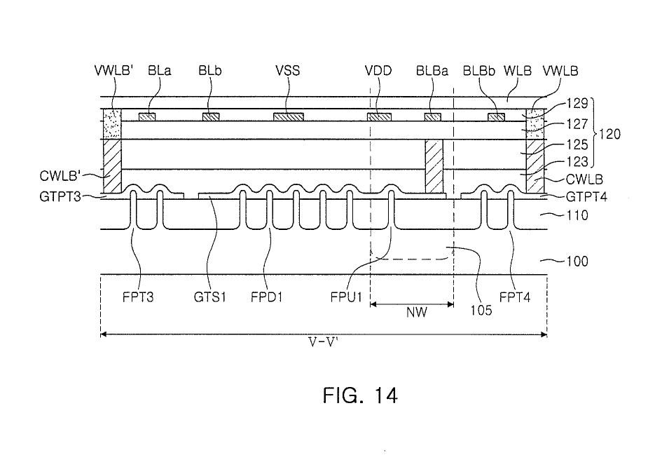

FIG. 13 illustrates a plan view of a memory device according to an exemplary embodiment of the present disclosure. Referring to FIG. 13, metal lines are illustrated in addition to the plan view of FIG. 11. For example, the additional metal lines illustrated in FIG. 13 may be the word lines WLA and WLB electrically connected to the gate electrodes GTPT1, GTPT2, GTPT3, and GTPT4 of the path transistors PT1 to PT4. Hereinafter, descriptions pertaining to a cross-section of the memory device illustrated in FIG. 13 taken along line V-V′ will be provided with reference to FIG. 14.

FIG. 14 illustrates a cross-sectional view of a memory device according to an exemplary embodiment of the present disclosure. Referring to FIG. 14, the plurality of fin structures FPT3, FPD1, FPU1, and FPT4 on the semiconductor substrate 100, the insulating layer 110 covering the space between the plurality of fin structures FPT3, FPD1, FPU1, and FPT4 and the semiconductor substrate 100, and the gate electrodes GTPT3, GTS1, and GTPT4 covering an upper portion of the plurality of fin structures FPT3, FPD1, FPU1, and FPT4 exposed without being covered by the insulating layer 110 are illustrated.

The second word line WLB may be electrically connected to the gate electrodes GTPT3 and GTPT4 of the third and fourth path transistors PT3 and PT4 through the vias VWLB and VWLB′ both penetrating through the third inter-insulating layer 127 and a fourth inter-insulating layer 129 formed on the third inter-insulating layer 127. The fourth inter-insulating layer 129 may electrically separate the word lines WLA and WLB from the bit lines BLa, BLb, BLBa, and BLBb, the power line VDD, and the ground line VSS.

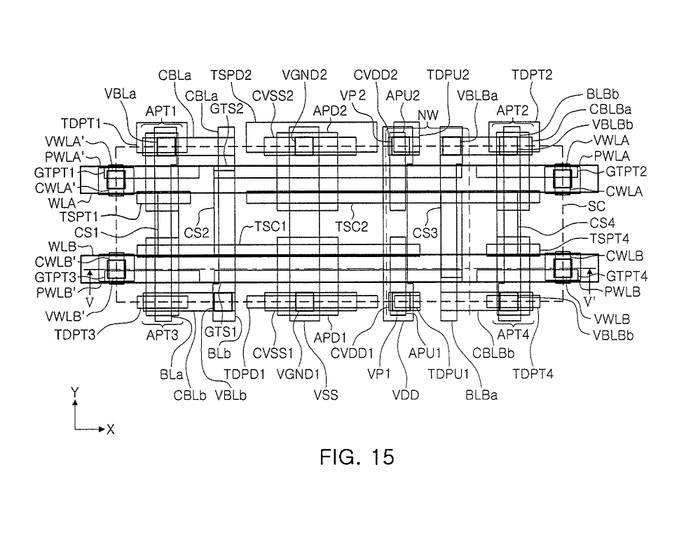

FIG. 15 illustrates a plan view of a memory device according to an exemplary embodiment of the present disclosure.

FIG. 15 illustrates a plan view of a memory device according to an exemplary embodiment in which the active regions of the transistors PU1, PU2, PD1, PD2, PT1, PT2, PT3, and PT4 are formed in a planar structure rather than the fin structure. Metal lines including, or example, a bit line, a power source, and a ground line, may be omitted in FIG. 15.

Referring to FIG. 15, a plurality of active regions APU1, APU2, APD1, APD2, APT1, APT2, APT3, and APT4 may be formed in the unit cell region SC of the memory device. In an embodiment, he plurality of active regions APU1, APU2, APD1, APD2, APT1, APT2, APT3, and APT4 may have, for example, a rectangular form. Each of the plurality of active regions APU1, APU2, APD1, APD2, APT1, APT2, APT3, and APT4 may extend along the second direction, a Y direction of FIG. 15.

The plurality of gate electrodes GTS1, GTS2, GTPT1, GTPT2, GTPT3, and GTPT4 may be disposed on the plurality of active regions APU1, APU2, APD1, APD2, APT1, APT2, APT3, and APT4 while extending along a first direction, e.g., an X axis direction of FIG. 15. The plurality of gate electrodes GTS1, GTS2, GTPT1, GTPT2, GTPT3, and GTPT4 may intersect the plurality of active regions APU1, APU2, APD1, APD2, APT1, APT2, APT3, and APT4. The first to fourth path transistors PT1 to PT4 may include the individually separated gate electrodes GTPT1, GTPT2, GTPT3, and GTPT4. The first pull-up and pull-down transistors PU1 and PD1 and the second pull-up and pull-down transistors PU2 and PD2 may share the shared gate electrodes GTS1 and GTS2. By the shared gate electrodes GTS1 and GTS2, the gate terminals of the first pull-up and pull-down transistors PU1 and PD1 may be connected to one another, and the gate terminals of the second pull-up and pull-down transistors PU2 and PD2 may be connected to one another.

In forming the gate electrodes GTS1, GTS2, GTPT1, GTPT2, GTPT3, and GTPT4, dummy gate electrodes extending along the first direction to form a gate spacer may be formed in three lines along the second direction, respectively. The gate spacer disposed in a lengthwise direction, for example, along the second direction, may be formed on lateral surfaces of the dummy gate electrodes, and the gate electrodes may not be formed in a central area of the unit cell region SC. Accordingly, an interval between the gate electrodes GTS2, GTPT1, and GTPT2 disposed in the same positions along the Y axis direction and the gate electrodes GTS1, GTPT3, GTPT4 disposed in the same positions along the Y axis direction may be sufficiently secured, and process stability may be increased.

According to exemplary embodiments, all of the active regions APU1, APU2, APD1, APD2, APT1, APT2, APT3, and APT4 may not intersect the unit cell region SC in the second direction. For example, the plurality of active regions APU1, APU2, APD1, APD2, APT1, APT2, APT3, and APT4 may be separated along the second direction.

The connectors TDPT1, TSPT1, TDPT2, TDPT3, TDPT4, TSPT4, TDPU1, TDPU2, TDPD1, TDPD2, TSC1, and TSC2 respectively connected to the plurality of active regions PU1, APU2, APD1, APD2, APT1, APT2, APT3, and APT4 may be disposed in four different positions divided in the second direction within the single unit cell region SC. The connectors TDPT1, TSPT1, TDPT2, TDPT3, TDPT4, TSPT4, TDPU1, TDPU2, TDPD1, TDPD2, TSC1, and TSC2 may be provided on both edges of the active regions PU1, APU2, APD1, APD2, APT1, APT2, APT3, and APT4, and may each provide the drain or source terminal of each of the transistors PU1, PU2, PD1, PD2, PT1, PT2, PT3, and PT4. Due to, for example, a structure of the active regions APU1, APU2, APD1, APD2, APT1, APT2, APT3, and APT4 being divided in the second direction within the unit cell region SC, the connectors TDPT1, TSPT1, TDPT2, TDPT3, TDPT4, TSPT4, TDPU1, TDPU2, TDPD1, TDPD2, TSC1, and TSC2 may be disposed in the four different positions divided in the second direction within the unit cell region SC.

Accordingly, a height along the second direction within the single unit cell region SC may be trisected based on a position in the second direction at which the connectors TDPT1 to TDPT4, TSPT1, TSPT4, TDPU1, TDPU2, TDPD1, TDPD2, TSC1, and TSC2 are disposed. For example, the memory device according to the exemplary embodiment may have a 3 CPP structure in which the height of the single unit cell region SC is trisected.

The connectors TDPT1, TSPT1, TDPT2, TDPT3, TDPT4, TSPT4, TDPU1, TDPU2, TDPD1, TDPD2, TSC1, and TSC2 may be connected to at least one of the contactors, e.g., contacts, CBLa, CBLb, CBLBa, CBLBb, CVSS1, CVSS2, CVDD1, CVDD2, CWLA, CWLB, CWLA′, CWLB′, CS1, CS2, CS3, and CS4. The contactors, e.g., contacts, CS1 to CS4 disposed within the unit cell region SC rather than on a boundary of the unit cell regions may electrically connect different connectors to one another, or a connector and a gate electrode one another. For example, nodes connecting the inverters INV1 and INV2 and the path transistors PT1 to PT4 using the contactors, e.g., contacts, CS1 to CS4 may be provided as illustrated in the circuit diagram of FIG. 1.

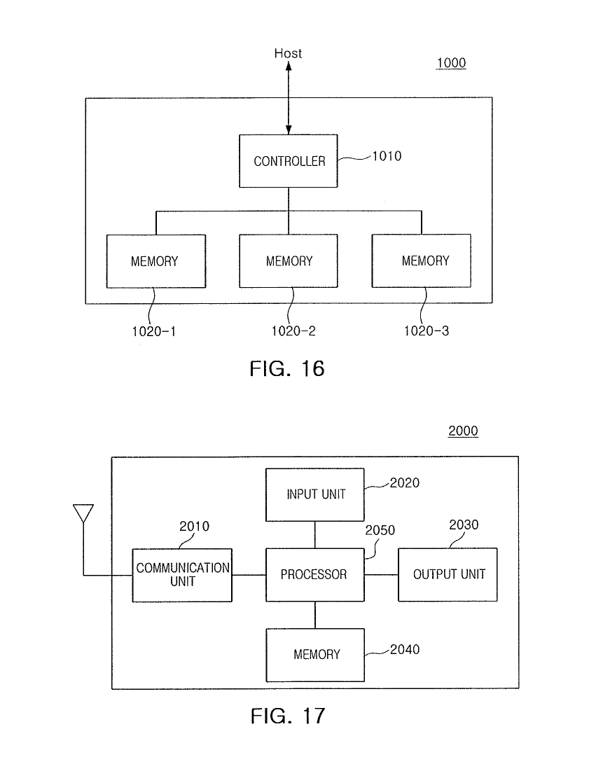

FIGS. 16 and 17 illustrate block diagrams of electronic devices including memory devices according to exemplary embodiments of the present disclosure.

Referring to FIG. 16, a storage device 1000 according to an exemplary embodiment of the present disclosure may include a controller 1010 communicating with a HOST, and memories 1020-1, 1020-2, and 1020-3 storing data. At least one of the memories 1020-1, 1020-2, and 1020-3 may include the memory device having the unit cell region SC according to the exemplary embodiments as provided hereinbefore, and the controller 1010 may be an SRAM controller.

The HOST communicating with the controller 1010 may include a variety of electronic devices in which the storage device 1000 is provided. The controller 1010 may receive a data write or a data read request transferred from HOST, and generate a command CMD for storing data in the memories 1020-1, 1020-2, and 1020-3 or fetching data from the memories 1020-1, 1020-2, and 1020-3.

FIG. 17 illustrates a block diagram of an electronic device including a non-volatile memory device according to an exemplary embodiment of the present disclosure.

Referring to FIG. 17, an electronic device 2000 may include a communication unit 2010, an input unit 2020, an output unit 2030, a memory 2040, and a processor 2050.

The communication unit 2010 may include a wired/wireless communications module, such as, for example, a wireless Internet module, a local area network (LAN) communications module, a global positioning system (GPS) module, and a mobile communications module. The wired/wireless communications module included in the communication unit 2010 may be connected to an external communication network by various communications standards to transceive data.

The input unit 2020 may be a module provided for a user to control an operation of the electronic device 2000, including, for example, a mechanic switch, a touch screen, and a voice recognition module. The input unit 2020 may include a mouse or a finger mouse device operating in a track ball or laser pointer scheme, and further include various sensor modules allowing a user to input data.

The output unit 2030 may output information processed in the electronic device 2000 in a form of voice or image. The memory 2040 may store a program or data for processing and controlling the processor 2050. The memory 2040 may include at least one non-volatile memory according to the exemplary embodiments described hereinbefore with reference to FIGS. 1 through 6 and FIG. 10. The processor 2050 may transfer a command to the memory 2040 based on a necessary operation, and store or fetch data.

The memory 2040 may communicate with the processor 2050 while being embedded in the electronic device 2000 or through the use of an additional interface. The memory 2040 may include the memory device having the unit cell region SC according to the exemplary embodiment described hereinbefore, and the processor 2050 may include an SRAM controller.

The processor 2050 may control an operation for each unit included in the electronic device 2000. The processor 2050 may perform a controlling and processing in association with, for example, a voice call, a video call, and data communications, or in associated with multimedia playing and management. The processor 2050 may process an input transferred from a user through the input unit 2020, and output the processing result through the output unit 2030. Further, the processor 2050 may store data required to control the operation of the electronic device 2000 in the memory 2040 or fetch data therefrom.

By way of summation and review, in an SRAM, a single unit cell may have a height corresponding to two contact poly pitches, 2CPP, or four contacted poly pitches, 4CPP. In a case of the 2CPP or 4CPP structure, a portion of path transistors may be turned on to allow a current transferred through a bit line to flow along a gate electrode, and a mismatch between path transistors may be caused in a fine process including less than 20 nanometers (nm).

According to an exemplary embodiment of the present disclosure, a DPSRAM layout including a 3 contacted poly pitch (3CPP) structure may be provided. According to such a layout, a single unit cell region may include a plurality of active regions, and a plurality of gate electrodes extending in a first direction. The plurality of active regions may extend in a second direction intersecting the first direction, e.g., orthogonal to the first direction, and may be separated in the second direction to be disposed in the 3CPP structure. In an embodiment, an SRAM layout based on the 3CPP structure may be provided by designing the layout in a manner in which an interval between gate electrodes included in the single unit cell region is greater than an interval between gate electrodes included in adjacent unit cell regions.

In an embodiment, a memory device may minimize a current path difference between path transistors in a dual-ported SRAM, and a mismatch between the path transistors may be reduced.

As set forth above, in the memory device according to the exemplary embodiments of the present disclosure, a current applied through each of a plurality of path transistors included in a single unit cell region in an SRAM may not pass through a gate electrode having a relatively high resistance value. According to the exemplary embodiments, an SRAM structure minimizing a mismatch between the plurality of path transistors and ensuring a sufficient gap between a word line and a bit line may be provided.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A memory device, comprising:
a substrate including unit cell regions;
active regions on the substrate; and
gate electrodes on the substrate and extending in a first direction and intersecting at least one of the active regions,
the active regions being adjacent to a boundary between the unit cell regions, and being separated from each other within the unit cell regions along a second direction orthogonal to the first direction.

2. The memory device as claimed in claim 1, further comprising:
first connectors on the boundary between the unit cell regions; and
second connectors between the gate electrodes within the unit cell regions,
wherein at least some of the second connectors are disposed in different positions along the second direction.

3. The memory device as claimed in claim 2, wherein each of the active regions includes at least one fin structure.

4. The memory device as claimed in claim 3, wherein at least some of the active regions include different numbers of fin structures.

5. The memory device as claimed in claim 3, wherein at least one of the second connectors electrically connects fin structures included in different active regions to one another.

6. The memory device as claimed in claim 5, wherein the at least one second connector electrically connecting fin structures included in the different active regions to one another is provided as a path through which a current applied to the different active regions flows.

7. The memory device as claimed in claim 2, wherein the first and second connectors include a metallic silicide.

8. The memory device as claimed in claim 1, wherein the active regions includes first conductive active regions and second conductive active regions.

9. The memory device as claimed in claim 8, wherein the gate electrodes includes:
at least one path gate electrode intersecting at least one of the first conductive active regions; and
at least one shared gate electrode intersecting the second conductive active regions and first conductive active regions not intersected by the at least one path gate electrode.

10. The memory device as claimed in claim 1, further comprising at least one contact electrically connected to the active regions and at least one contact electrically connected to at least one of the gate electrodes.

11. The memory device as claimed in claim 10, wherein the at least one contact connected to the active regions and the at least one contact connected to the gate electrodes have different heights from one another.

12. A memory device, comprising:
a substrate including unit cell regions;
active regions on the substrate; and
gate electrodes intersecting at least one of the active regions,
an interval between the gate electrodes in parallel in a single unit cell region from among of the unit cell regions being greater than an interval between the gate electrodes in parallel in adjacent unit cell regions from among the unit cell regions.

13. The memory device as claimed in claim 12, wherein the interval between the gate electrodes in parallel in the single unit cell region is two times greater than the interval between the gate electrodes in parallel in the adjacent unit cell regions.

14. The memory device as claimed in claim 12, wherein the active regions include:
first conductive active regions; and
second conductive active regions,
the gate electrodes including:
at least one path gate electrode; and
at least one shared gate electrode,
at least one of the first conductive active regions intersecting the at least one path gate electrode, and the second conductive active regions and first conductive active regions not intersecting the at least one path gate electrode intersect the at least one shared gate electrode.

15. The memory device as claimed in claim 14, further comprising connectors electrically connected to at least one of the first conductive active regions and the second conductive active regions.

16. The memory device as claimed in claim 15, wherein the connectors includes:
first connectors on a boundary between the unit cell regions; and
second connectors within the unit cell regions.

17. The memory device as claimed in claim 16, wherein the second connectors are in parallel with the at least one path gate electrode and the at least one shared gate electrode.

18. The memory device as claimed in claim 16, wherein the second connectors are provided as a path through which a current transferred from the at least one of the first conductive active regions intersecting the at least one path gate electrode flows.

19. The memory device as claimed in claim 15, wherein:
each of the active regions includes at least one fin structure, and
two or more fin structures included in the active regions are electrically connected to one another by the connectors.

20.-24. (canceled)

25. A memory device, comprising:
a substrate;
active regions on the substrate, each of the active regions including at least one fin structure and an insulating layer between adjacent fin structures in a first direction; and
gate electrodes on the insulating layer and extending in the first direction and intersecting at least one of the active regions,
an upper portion of fin structures exposed outward of the insulating layer being covered by one of the gate electrodes.
